(19) United States
(12) Patent Application Publication
(10) Pub. No.: US 2026/0251724 A1
(43) Pub. Date: Aug. 27, 2026

(54) DEVICE MONITORING METHOD, APPARATUS AND SYSTEM

(71) Applicant: CRSC COMMUNICATION & INFORMATION GROUP COMPANY LTD., Beijing (CN)

(72) Inventors: Jing LUO, Beijing (CN); Feng XUE, Beijing (CN); Dong FEI, Beijing (CN); Ping FENG, Beijing (CN); Haijun HU, Beijing (CN); Jialiang ZHOU, Beijing (CN)

(21) Appl. No.: 18/995,356

(22) PCT Filed: Aug. 23, 2023
(86) PCT No.: PCT/CN2023/114391

§ 371 Date: Jan. 16, 2025

(30) Foreign Application Priority Data
Jan. 30, 2023 (CN) 202310093873.0

(51) Int. Cl. G01R 31/392; G01K 3/00; G01R 31/3842; G01R 31/389; G01R 31/396; H01M 10/42; H02J 7/84

(52) U.S. Cl. CPC G01R 31/392; G01K 3/005; G01R 31/3842; G01R 31/389; G01R 31/396; H01M 10/4285; H02J 7/84

(57) ABSTRACT

The present disclosure relates to the field of device monitoring, and relates to a device monitoring method, apparatus and system. The method includes: remotely acquiring data of a controlled device in a network interconnection mode to obtain telemetry data, which is data representing the real-time working state of the controlled device; determining whether to generate alarm information according to the telemetry data, the alarm information being used for representing that the controlled device is in an abnormal working state; and in a case where it is determined that the alarm information is generated, adjusting the controlled device in the adjustment mode matched with the device type of the controlled device according to the alarm information.

### TECHNICAL FIELD

The present disclosure relates to the field of device monitoring technology, and in particular, to a device monitoring method, apparatus, system, electronic device, and storage medium.

### BACKGROUND

As the number of computer systems and communication devices continue to increase, the central equipment room has become the heart of business management for various companies, organizations and the like. In addition, each central equipment room has a corresponding power distribution device provided therein.

### SUMMARY

The present disclosure provides a device monitoring method, apparatus, system, electronic device, and storage medium, which solve the problem of how to improve the operation safety of the device.

In a first aspect, an embodiment of the present disclosure provides a device monitoring method, including: remotely acquiring data of a controlled device in a network interconnection mode to obtain telemetry data, which is data representing a real-time working state of the controlled device; determining whether to generate alarm information according to the telemetry data, the alarm information being used for representing that the controlled device is in an abnormal working state; and in a case where it is determined that the alarm information is generated, adjusting the controlled device in the adjustment mode matched with the type of the controlled device according to the alarm information.

In a second aspect, an embodiment of the present disclosure provides a device monitoring apparatus, which includes: a data acquisition module configured to remotely acquire data of a controlled device in a network interconnection mode to obtain telemetry data, which is data representing a real-time working state of the controlled device; a generation module configured to determine whether to generate alarm information according to the telemetry data, the alarm information being used for representing that the controlled device is in an abnormal working state; and an adjustment module configured to, in a case where it is determined that the alarm information is generated, adjust the controlled device in the adjustment mode matched with the type of the controlled device according to the alarm information.

In a third aspect, an embodiment of the present disclosure provides a device monitoring system, which includes: a controlled device, a server, and a device monitoring apparatus; where the device monitoring apparatus is electrically connected to the server and the controlled device; the controlled device includes at least one first type device having computation processing capability and at least one second type device having no computation processing capability and passively receiving control information; the device monitoring apparatus is configured to perform any one of the device monitoring methods according to the embodiments of the present disclosure; and the server is configured to, based on a communication interface provided by a preset communication converter, acquire the telemetry data acquired by the device monitoring apparatus and operation data of the first type device, store the telemetry data and the operation data, interact with the first type device through the device monitoring apparatus, and provide preset service information for the first type device.

In a fourth aspect, an embodiment of the present disclosure provides an electronic device, which includes a memory, a processor, and a computer program stored in the memory and executable on the processor, where the processor, when executing the computer program, implements any one of the device monitoring methods according to the embodiments of the present disclosure.

In a fifth aspect, an embodiment of the present disclosure provides a computer-readable storage medium, on which a computer program is stored, where the computer program, when executed by the processor, implements any one of the device monitoring methods according to the embodiments of the present disclosure.

According to the device monitoring method, apparatus, system, electronic device, and storage medium of the present disclosure, data of the controlled device is remotely acquired in a network interconnection mode to obtain telemetry data, and a real-time working state of the controlled device can be obtained based on the telemetry data, which facilitates processing of the controlled device; whether to generate alarm information is determined based on the telemetry data, the alarm information being used for representing that the controlled device is in an abnormal working state and requires timely processing to reduce fault rate; in a case where it is determined that the alarm information is generated, the controlled device is adjusted in an adjustment mode matched with a type of the controlled device, so that the controlled device can work under a normal working condition, which increases the safety and reliability of monitoring of the equipment room environment and the power distribution device.

It is to be understood that both the foregoing general description and the following detailed description are exemplary and explanatory only and are not intended to limit the present disclosure. Other features and aspects of the present disclosure will become apparent from the following detailed description of the exemplary embodiments, which proceeds with reference to the accompanying drawings.

### BRIEF DESCRIPTION OF DRAWINGS

FIG. 1 shows a schematic flowchart of a device monitoring method provided by an embodiment of the present disclosure.

FIG. 2 shows a schematic flowchart of a device monitoring method provided by an embodiment of the present disclosure.

FIG. 3 is a block diagram illustrating the configuration of a device monitoring apparatus provided by an embodiment of the present disclosure.

FIG. 4 is a block diagram illustrating the configuration of a device monitoring apparatus provided by an embodiment of the present disclosure.

FIG. 5 is a block diagram illustrating the configuration of a device monitoring system provided by an embodiment of the present disclosure.

FIG. 6 is a block diagram illustrating the configuration of a device monitoring system provided by an embodiment of the present disclosure.

FIG. 7 shows a schematic view of operation control of a device monitoring system of an embodiment of the present disclosure.

FIG. 8 is a block diagram illustrating the configuration of an electronic device provided by an embodiment of the present disclosure.

FIG. 9 is a block diagram illustrating the configuration of an electronic device provided by an embodiment of the present disclosure.

### DETAIL DESCRIPTION OF EMBODIMENTS

The embodiments of the present disclosure are described in further detail below with reference to the accompanying drawings. It should be understood that the embodiments described herein below are merely used to describe and explain the present disclosure only and are not intended to limit the present disclosure. It will be apparent to a person skilled in the art that the present disclosure may be practiced without some of these specific details. The following description of the embodiments is merely intended to provide a better understanding of the present disclosure by illustrating examples thereof.

At present, in a power and environment monitoring system of an equipment room, the following problems exist in the monitoring of non-intelligent devices such as storage batteries and the like. When data such as current, voltage and the like of a single battery is acquired, the acquired data is generally summarized and reported step by step, and the faults cannot be processed in time. In addition, the ambient temperature around the device cannot be sensed, and the floating charge voltage cannot be correspondingly compensated, so that the service life of the storage battery is shortened. When a battery pack is monitored using a traditional monitoring method, the corresponding maintenance workload is large, time-and-labor-consuming, without an effective maintenance of the battery pack. For example, in the process of checking the discharge test of the storage battery in an online manner, deviation exists in the discharge depth measurement of the storage battery, a constant flow is impossible in the discharge process, the remaining capacity of the storage battery cannot be accurately tested, thus the storage battery cannot be controlled with precision and accuracy, and the power supply safety is reduced.

In view of the above existing problems, a device monitoring method, apparatus, system, electronic device, and storage medium are provided to solve the above problems.

To make the objects, technical solutions and advantages of the present disclosure more apparent, the implementation of the present disclosure will be described in detail with reference to the accompanying drawings.

In a first aspect, an embodiment of the present disclosure provides a device monitoring method. The device monitoring method according to the embodiment of the present disclosure may be executed by a corresponding device monitoring apparatus, which may be implemented in a software and/or hardware manner, and can be generally integrated in an electronic device.

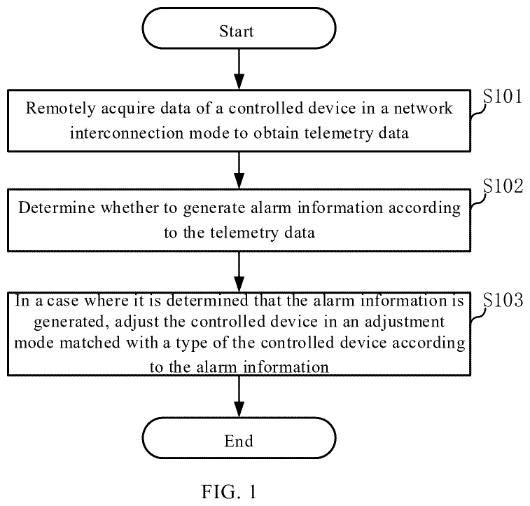

FIG. 1 shows a flowchart of a device monitoring method provided by an embodiment of the present disclosure. The method can be applied to a device monitoring apparatus. As shown in FIG. 1, the device monitoring method includes, but is not limited to, the following steps S101 to S103.

Step S101, remotely acquiring data of a controlled device in a network interconnection mode to obtain telemetry data.

The telemetry data is data representing a real-time working state of the controlled device. For example, the telemetry data may include: at least one of battery pack capacity, battery pack voltage, battery voltage, ambient temperature, battery pack temperature, Printed Circuit Board Assembly (PCBA) temperature, battery temperature, battery pack charging current, battery pack discharging current, battery pack internal resistance, or battery pack health state information.

S102, determining whether to generate alarm information according to the telemetry data.

The alarm information is used for representing that the controlled device is in an abnormal working state.

S103, in a case where it is determined that the alarm information is generated, adjusting the controlled device in an adjustment mode matched with a type of the controlled device according to the alarm information.

In this embodiment, by remotely acquiring data of the controlled device in a network interconnection mode to obtain telemetry data, the real-time working state of the controlled device can be obtained based on the telemetry data, which facilitates processing of the controlled device; and whether to generate alarm information is determined based on the telemetry data, where the alarm information is used for representing that the controlled device is in an abnormal working state and requires timely processing, so that the fault rate is reduced; in a case where it is determined that alarm information is generated, the controlled device is adjusted in an adjustment mode matched with the type of the controlled device, so that the controlled device can work under a normal working condition, which increases the safety and reliability of monitoring of the equipment room environment and the power distribution device.

In some optional embodiments, the controlled device includes a first type device having computation processing capability (e.g., an intelligent device such as a switch or a router), and a second type device having no computation processing capability and passively receiving control information (e.g., a non-intelligent device such as a battery pack or a power supply unit).

In some optional embodiments, the second type device includes a storage battery, which refers to a rechargeable battery that may be a single battery or a battery pack including a plurality of batteries.

For example, the second type device includes at least one of a lead-acid storage battery, a lead-acid storage battery pack, a lithium series battery, or a lithium series battery pack.

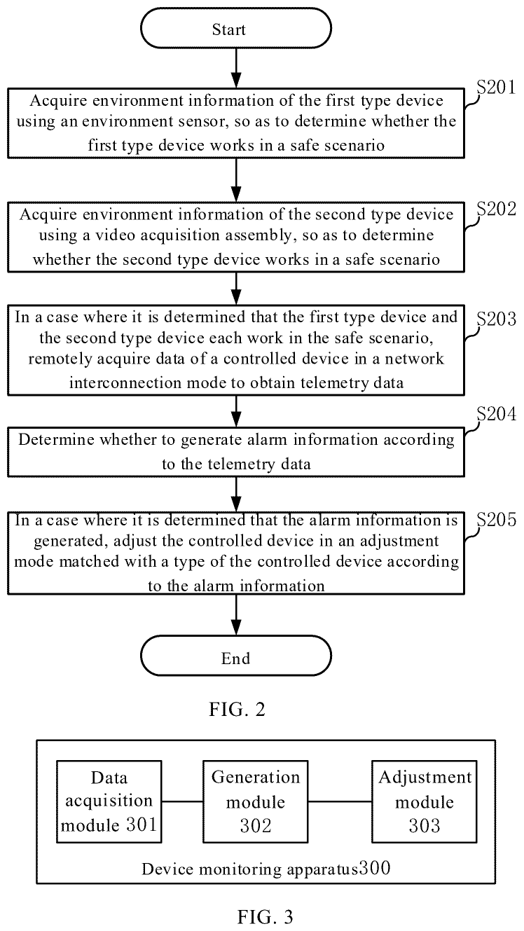

For example, FIG. 2 shows a schematic flowchart of a device monitoring method provided by an embodiment of the present disclosure. The method can be applied to a device monitoring apparatus. As shown in FIG. 2, the device monitoring method includes, but is not limited to, the following steps S201 to S205.

Step S201, acquiring environment information of the first type device using an environment sensor, so as to determine whether the first type device works in a safe scenario.

For example, the environment information of the first type device includes: ambient temperature, ambient humidity, whether there is water immersion problem, illumination information, and the like of the first type device.

The environment where the first type device is located is judged through the environment information acquired by the environment sensor so as to determine that no dangerous information exists around the first type device (for example, no water immersion problem exists, or the temperature and humidity are within a preset range, and the illumination is sufficient so that the information corresponding to the device can be acquired, and etc.), that is, to determine that the first type device works in a safe scenario, so as to facilitate processing of the first type device and improve the safety of the device.

Step S202, acquiring environment information of the second type device using a video acquisition assembly, so as to determine whether the second type device works in a safe scenario.

The video acquisition assembly may include a video camera, a camera, a smart phone and other apparatuses capable of acquiring video images.

By acquiring the environment information of the second type device using a video acquisition assembly, the environment information of the second type device can be visually acquired from the video image, the working condition of the second type device (namely, non-intelligent device) can be conveniently known, and the troubleshooting force over potential safety hazards of the second type device can be promoted, so that the second type device can work in a safe scenario.

Step S203, in a case where it is determined that the first type device and the second type device each work in the safe scenario, remotely acquiring data of the controlled device in a network interconnection mode to obtain telemetry data.

Step S204, determining whether to generate alarm information according to the telemetry data.

Step S205, in a case where it is determined that the alarm information is generated, adjusting the controlled device in an adjustment mode matched with a type of the controlled device according to the alarm information.

It should be noted that steps S203 to S205 in this embodiment are identical to steps S101 to S103 in the previous embodiment, thus are not repeated herein.

In this embodiment, by remotely acquiring data of the controlled device in a network interconnection mode to obtain telemetry data in a case where it is determined that the first type device and the second type device each work in the safe scenario, the telemetry data obtained is more accurate; by determining whether to generate alarm information based on the telemetry data and further performing timely processing on the controlled device based on the alarm information to reduce the fault rate, the maintenance of the controlled device is more scientific and the service life of the controlled device is effectively prolonged; and by adjusting the controlled device in an adjustment mode matched with the type of the controlled device according to the alarm information in a case where it is determined that the alarm information is generated, the controlled device can work in a normal state, which improves the safety and reliability of monitoring of the equipment room and the power distribution device.

In some optional embodiments, the controlled device includes a storage battery, and remotely acquiring data of a controlled device in a network interconnection mode to obtain telemetry data in step S101 or step S203 includes: remotely acquiring the telemetry data of the controlled device in a network interconnection mode based on a preset acquisition period.

The telemetry data includes at least one of a working parameter, temperature information, or battery capacity information of the storage battery. For example, the working parameter is a relevant parameter of the controlled device during operation, such as the working voltage, working current, and the like.

Through a preset acquisition period (for example, 10 minutes, or 20 minutes, etc.), the telemetry data of the controlled device can be acquired remotely at intervals in a network interconnection mode, so that the working state of the controlled device can be monitored remotely, and the possibility of failure of the controlled device is reduced. In addition, when a query instruction fed back by a user is received, the telemetry data of the controlled device can be inquired based on the information included in the query instruction, so that the user can know the state of the controlled device in real time, the real-time monitoring capability toward the controlled device is improved, and the controlled device can work normally.

In some embodiments, the telemetry data may be acquired as follows: acquiring telemetry data of the controlled device in response to a query instruction. The controlled device and the current device may be directly connected for communication, or may communicate in a network interconnection mode.

In some optional embodiments, determining whether to generate alarm information based on the telemetry data in step S102 or step S204 includes: generating state of health overlimit alarm information in a case where it is determined that the telemetry data includes the state of health of the controlled device and the state of health exceeds a preset health threshold; generating temperature alarm information in a case where it is determined that the telemetry data includes a temperature value of the controlled device and the temperature value is not within a preset temperature range; and generating working parameter alarm information in a case where it is determined that the telemetry data includes a working parameter of the controlled device and the working parameter is not within a preset parameter range.

The state of health is the ratio of the actual capacity of the storage battery to the preset capacity of the storage battery. For example, the state of health of the battery is calculated using the following formula: actual capacity of the storage battery/preset capacity of the storage battery*100%, so that it can be accurately determined whether the storage battery is healthy, i.e. whether the storage battery can work normally.

If the state of health of the storage battery exceeds a preset health threshold, it indicates that a potential safety hazard exists in the storage battery, thus state of health overlimit alarm information is generated, and the operation and maintenance personnel can know the storage battery with the potential safety hazard, which is then maintained and repaired, thereby prolonging the service life of the storage battery.

When the temperature value of the controlled device is not within the preset temperature range, it indicates that the controlled device may have an excessively high or low temperature fault, for example, some components in the controlled device are damaged due to the excessively high temperature, and the components need to be replaced in time so that the controlled device can work normally. If the temperature is too low, it may indicate that the ambient temperature around the controlled device is too low (for example, the ambient temperature is −10 degrees, etc.), which would likely cause freezing of the controlled device, and a timely warm-keeping process needs to be performed on the controlled device, so that the controlled device can work normally.

Furthermore, the working parameter of the controlled device can be judged. When the working parameter is not within the preset parameter range, it indicates that differences exist in some working performances of the controlled device, thus working parameter alarm information is generated, so that the operation and maintenance personnel can be reminded to check the controlled device in time and determine whether the controlled device encounters faults, thereby prolonging the service life of the controlled device.

In some optional embodiments, adjusting the controlled device in an adjustment mode matched with a type of the controlled device according to the alarm information in step S103 or step S205 includes:
in a case where it is determined that the controlled device is a storage battery and the alarm information is state of health overlimit alarm information, balancing the storage battery so that the state of health of the storage battery meets a preset health threshold; and in a case where it is determined that the controlled device is a storage battery and the alarm information is working parameter alarm information, adjusting the charging parameter or the discharging parameter of the storage battery so that the working parameter of the storage battery meets a preset parameter range.

When different alarm information is acquired, the storage battery is processed in a processing mode matched with the alarm information, for example, balancing the capacity of the storage battery, or adjusting the charging parameter or discharging parameter of the storage battery, so that the storage battery can be restored to a normal working state as soon as possible, and the working performance of the storage battery can be improved.

Through alarm information in different dimensions and by adopting a processing mode matched with the alarm information, the storage battery can be monitored in time, and the service life of the storage battery can be prolonged.

In some optional embodiments, balancing the storage battery so that the state of health of the storage battery meets the preset health threshold includes: acquiring remaining capacities of a plurality of battery cells in the storage battery; in a case where it is determined that the remaining capacity of at least one battery cell is not within the preset capacity threshold range, generating, via an access control unit, a balancing battery cell by controlling the connection relationship between the balancing resistor and the at least one battery cell; and balancing the storage battery based on the balancing battery cell, so that the state of health of the storage battery meets a preset health threshold.

The at least one battery cell may be 2, 3 or other different numbers of battery cells, and each battery cell is connected to a balancing resistor, so that the battery cell can be balanced based on adjustment of the balancing resistor.

The connection relationship between the balancing resistor and the battery cell may include series connection or parallel connection. For example, the balancing resistor and the battery cell are connected in series via an access control unit, or the balancing resistor and the battery cell are connected in parallel via an access control unit, so that the obtained balancing battery cell can meet the corresponding capacity requirement under the action of the balancing resistor, the problems of battery damage (such as capacity attenuation) caused by overcharging of the battery and the like are reduced, the voltage consistency of the plurality of battery cells in the storage battery is maintained, the service life of the battery is prolonged, and the safety of the battery is improved.

For another example, the balancing resistor and the battery cell can also be connected in series or in parallel using an access control unit when the battery is discharged, so that the balancing resistor can consume the redundant capacity, the loss of the battery is reduced, and the operation reliability of the storage battery device is improved.

In some optional embodiments, the working parameter of the controlled device includes: at least one of voltage information, current information, or internal resistance information.

In a case where it is determined that the telemetry data includes a working parameter of the controlled device and the working parameter is not within a preset parameter range, generating working parameter alarm information includes: generating voltage alarm information in a case where it is determined that the telemetry data includes voltage information of the controlled device and the voltage of the controlled device is not within a preset voltage threshold range; generating current alarm information in a case where it is determined that the telemetry data includes current information of the controlled device and that current of the controlled device exceeds a preset current threshold; and generating internal resistance overlimit alarm information in a case where it is determined that the telemetry data includes internal resistance information of the controlled device and that an internal resistance value exceeds a preset internal resistance threshold.

By measuring the working condition of the controlled device through working parameters in different dimensions, the controlled device can be monitored comprehensively, which ensures that the controlled device works in a normal range, reduces the fault rate of the controlled device, and prolongs the service life of the controlled device.

In some optional embodiments, in a case where it is determined that the controlled device is a storage battery, the alarm information includes: alarm information that the battery capacity of the storage battery (or the battery pack capacity of the storage battery) is lower than a preset capacity.

The adjusting the controlled device in an adjustment mode matched with a type of the controlled device according to the alarm information in step S103 or step S205 includes: charging the storage battery in an intermittent charging mode and/or a current-limited charging mode so that the battery capacity of the storage battery meets a preset capacity.

The intermittent charging mode is a mode of charging the storage battery once at a preset interval, so that the storage battery can fully absorb the charged capacity, the problem of overlarge local voltage is reduced, the capacity in the storage battery is balanced, and the service life of the storage battery is prolonged.

The current-limited charging mode meets the requirement of the storage battery on battery capacity by limiting the charging current, for example, by charging the storage battery at a preset current value.

Alternatively, the storage battery is charged at a preset current value in a certain time period, and is charged at other current values in another time period so that the storage battery obtains different battery capacities in different periods, satisfying the requirement of the storage battery on the capacity in different periods, thereby achieving a preset capacity, and improving the use efficiency of the storage battery.

In some optional embodiments, the controlled device includes a storage battery, and the alarm information further includes: at least one of battery polarity reversal alarm information of the storage battery, battery pack polarity reversal alarm information of the storage battery, or sensor failure alarm information of the controlled device.

The sensor of the controlled device is used for sensing a working parameter of the controlled device. For example, a temperature sensor is used to sense a real-time temperature of the controlled device or an ambient temperature around the controlled device and the like, and a voltage control sensor is used to sense a working voltage and the like of the controlled device during operation. The above sensors are only examples, and may be specifically set according to practical needs, and other sensors not described are also within the protection scope of the present disclosure, and are not described herein again.

If the sensor of the controlled device cannot work normally (i.e., the sensor fails), sensor failure alarm information of the controlled device is generated, so that the operation and maintenance personnel can timely know that the sensor cannot work normally and need to be maintained or replaced, so as to achieve better monitoring of the controlled device and improve the working performance of the controlled device.

The battery pack polarity reversal alarm information of the storage battery is used for representing the occurrence of reversal of the positive electrodes and negative electrodes of certain battery cells in the battery pack. At this time, the internal consumption of the battery cells is increased, which would cause abnormal working conditions of the battery cells. By adopting a battery pack polarity reversal alarm, the operation and maintenance personnel can be warned in time to check the condition of polarity reversal, and the battery cells with polarity reversal can be adjusted in time, so that the battery cells can work normally, avoiding the scrapping of the battery cells and prolonging the service life of the battery pack.

It should be understood that the above embodiment may also be used in combination with any other manner of embodiments of the present disclosure. The above embodiment is only a specific example of the disclosure, and is not intended to limit the scope of the disclosure.

In a second aspect, an embodiment of the present disclosure provides a device monitoring apparatus, which is a corresponding apparatus for implementing the device monitoring method provided by the above embodiments of the present disclosure, and the apparatus may be implemented in a software and/or hardware manner, and can be generally integrated in an electronic device.

FIG. 3 is a block diagram illustrating the configuration of a device monitoring apparatus provided by an embodiment of the present disclosure. As shown in FIG. 3, the device monitoring apparatus 300 includes, but is not limited to, the following modules:
a data acquisition module 301 configured to remotely acquire data of a controlled device in a network interconnection mode to obtain telemetry data, which is data representing a real-time working state of the controlled device;
a generation module 302 configured to determine whether to generate alarm information according to the telemetry data, the alarm information being used for representing that the controlled device is in an abnormal working state; and
an adjustment module 303 configured to, in a case where it is determined that the alarm information is generated, adjust the controlled device in an adjustment mode matched with a type of the controlled device according to the alarm information.

It should be noted that the device monitoring apparatus 300 in this embodiment can execute any device monitoring methods according to the embodiments of the present disclosure.

In this embodiment, data of the controlled device is remotely acquired through a data acquisition module in a network interconnection mode to obtain telemetry data, and a real-time working state of the controlled device can be obtained based on the telemetry data, which facilitates processing of the controlled device; whether to generate alarm information is determined through a generation module based on the telemetry data, the alarm information being used for representing that the controlled device is in an abnormal working state and requires timely processing to reduce fault rate; and in a case where it is determined that the alarm information is generated, the controlled device is adjusted through an adjustment module in an adjustment mode matched with the type of the controlled device according to the alarm information, so that the controlled device can work under a normal working condition, which increases the safety and reliability of monitoring of the equipment room environment and the power distribution device.

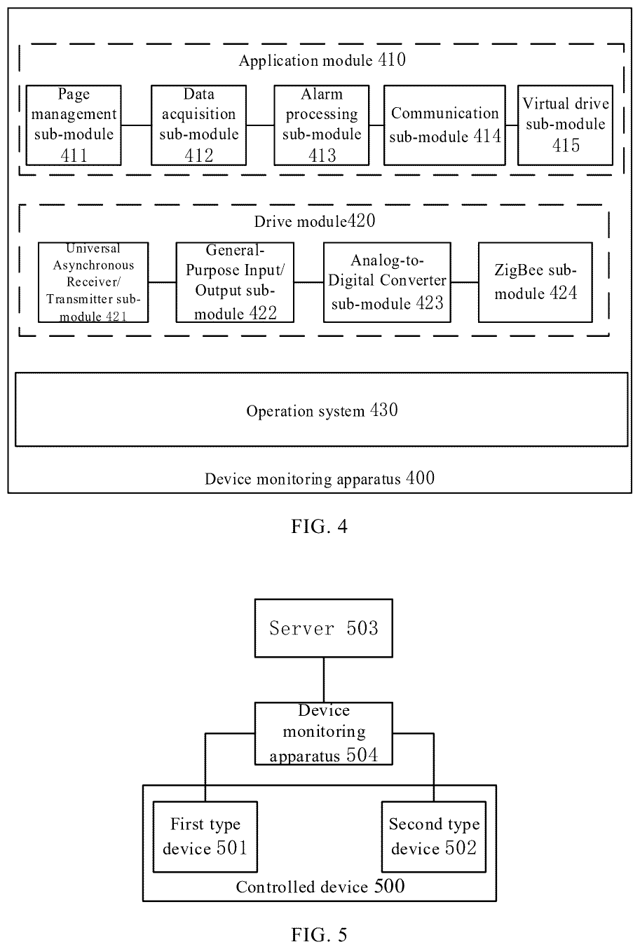

FIG. 4 is a block diagram illustrating the configuration of a device monitoring apparatus provided by an embodiment of the present disclosure. As shown in FIG. 4, the device monitoring apparatus 400 includes, but is not limited to, the following modules: an application module 410, a drive module 420, and an operation system 430.

The application module 410 includes a page management sub-module 411, a data acquisition sub-module 412, an alarm processing sub-module 413, a communication sub-module 414, and a virtual drive (Daemon) sub-module 415, which are connected in sequence.

The drive module 420 includes a Universal Asynchronous Receiver/Transmitter (UART) sub-module 421, a General-Purpose Input/Output (GPIO) sub-module 422, an Analog-to-Digital Converter (ADC) sub-module 423, and a ZigBee sub-module 424, which are connected in sequence.

The operation system 430 may be an Android system, or may be a module used by another operation system (e.g., a linux operation system or a windows operation system) to manage and control other modules. The above are only examples, and specific settings may be made according to practical needs, and other operation systems that are not described are also within the protection scope of the present disclosure, and are not described herein again.

The main functions of the device monitoring apparatus 400 are: using a data acquisition sub-module 412 to acquire data of monitored objects (such as an exchanger, storage battery apparatus, and various collectors for environment monitoring); using an alarm processing sub-module 413 to receive alarm data, working state and operating parameters of the monitored object.

It should be noted that, the respective modules related in this embodiment are all logical modules. In practical applications, one logical unit may be one physical unit, or a part of one physical unit, and may also be implemented by a combination of a plurality of physical units. In addition, in order to highlight the innovative part of the present disclosure, elements that are less closely related to solving the technical problem proposed by the present disclosure are not introduced in this embodiment, but it does not indicate that no other elements are present in the embodiment.

In a third aspect, an embodiment of the present disclosure provides a device monitoring system.

FIG. 5 is a block diagram illustrating the configuration of a device monitoring system provided by an embodiment of the present disclosure. As shown in FIG. 5, the device monitoring system includes, but is not limited to, the following devices: a controlled device 500, a server 503, and a device monitoring apparatus 504.

The device monitoring apparatus 504 is electrically connected to the server 503 and the controlled device 500; the controlled device 500 includes at least one first type device 501 and at least one second type device 502.

The first type device 501 is a device having computation processing capability. Therefore, the first type device 501 may be configured to perform the following data processing: acquiring, based on the computation processing capability of the first type device 501 itself, preset service information provided by the server 503 through interaction of the device monitoring apparatus 504 and the server 503.

The second type device 502 is a device having no computation processing capability and passively receiving control information, and the second type device 502 may also provide power or environment monitoring information for the first type device 501.

The device monitoring apparatus 504 is configured to perform any one of the device monitoring methods in the embodiments of the present disclosure.

The server 503 is configured to, based on a communication interface provided by a preset communication converter, obtain the telemetry data and the operation data of the first type device 501 acquired by the device monitoring apparatus 504, store the telemetry data and the operation data, interact with the first type device 501 through the device monitoring apparatus 504, and provide preset service information for the first type device 501.

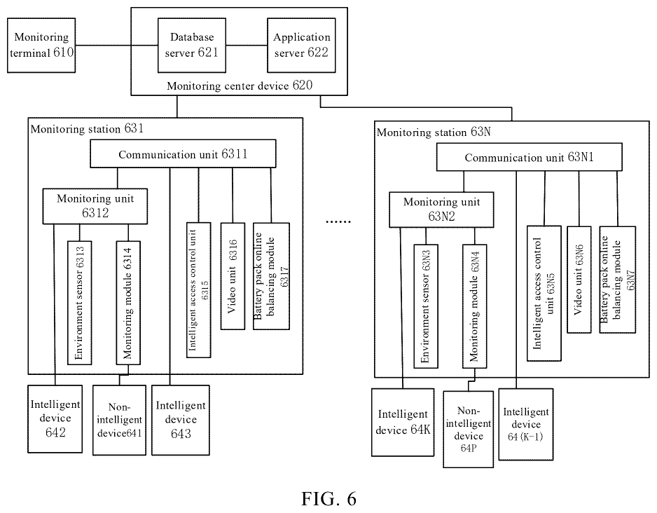

FIG. 6 is a block diagram illustrating the configuration of a device monitoring system provided by an embodiment of the present disclosure. As shown in FIG. 6, the device monitoring system includes, but is not limited to, the following devices: a monitoring terminal 610, a monitoring center device 620, a plurality of monitoring stations 631/63N, a non-intelligent device 641, an intelligent device 642, an intelligent device 643, an intelligent device 64K, a non-intelligent device 64P, and an intelligent device 64 (K−1).

N represents the number of monitoring stations, P represents the number of non-intelligent devices, K represents the number of intelligent devices, and N, P and K are integers greater than or equal to 1. The intelligent device 64K corresponds to the first type device 501 in FIG. 5 and the non-intelligent device 64P corresponds to the second type device 502 in FIG. 5.

It should be noted that the number of the non-intelligent devices is the same as the number of the monitoring modules, that is, one monitoring module corresponds to one non-intelligent device.

The monitoring center device 620 includes a database server 621 and an application server 622. The database server 621 is intended to store alarm data and operation data of the device, and the like. The application server 622 is intended to mount a platform of the device monitoring system (e.g., an equipment room power and environment monitoring system), and provide a business service function for the device monitoring system.

The monitoring station 631 includes the following modules: a communication unit 6311, a monitoring unit 6312, an environment sensor 6313, a monitoring module 6314, an intelligent access control unit 6315, a video unit 6316, and a storage battery pack balancing module 6317; . . . ; the monitoring station 63N includes the following modules: a communication unit 63N1, a monitoring unit 63N2, an environment sensor 63N3, a monitoring module 63N4, an intelligent access control unit 63N5, a video unit 63N6, and a storage battery pack balancing module 63N7.

The monitoring unit 6312 is connected to the intelligent device 642, the monitoring module 6314 is connected to the non-intelligent device 641, and the communication unit 6311 is connected to the intelligent device 643; . . . , the monitoring unit 63N2 is connected to the intelligent device 64K, the monitoring module 63N4 is connected to the non-intelligent device 64P, and the communication unit 63N1 is connected to the intelligent device 64 (K−1).

The communication unit 6311 may communicate with other units or modules through a 485 interface, and the monitoring station 631 may communicate with the monitoring terminal device 620 through a network communication interface supporting a Transmission Control Protocol (TCP) or an IP Protocol.

For example, the monitoring unit 6312 can acquire information of a plurality of intelligent devices in time, so as to monitor the working operation states of the plurality of intelligent devices; in addition, the monitoring unit 6312 further monitors and acquires the working operation state (or voltage information, current information, etc.) of the non-intelligent device 641 through the monitoring module 6314, so that the various different devices can keep working normally, thereby improving the overall operation efficiency of the system.

The environment sensor 6313 can monitor information of the environment (e.g., temperature information, humidity information) where the device is located; the video unit 6316 performs real-time image monitoring on the device to ensure that there is no abnormality in the operation environment of the device.

The non-intelligent device 641 (e.g., a storage battery, etc.) is monitored using the monitoring module 6314, so as to obtain the remaining capacities of the plurality of battery cells in the storage battery. In a case where it is determined that the remaining capacities of the battery cells are different from the preset capacity threshold, the working state of the storage battery pack balancing module 6317 is controlled using the intelligent access control unit 6315, for example, controlling the connection relationship between the balancing resistor and the battery cells (for example, adopting a parallel or series connection relationship, etc.), so as to generate a balancing battery cell. The storage battery is balanced based on the balancing battery cell so that the state of health of the storage battery meets a preset health threshold.

For example, the storage battery pack online balancing module 6317 controls the resistance switching circuit (e.g., the intelligent access control unit 6315) through a controller (e.g., the monitoring unit 6312), so as to connect the balancing resistor to a certain battery cell in the storage battery pack, so that balancing measurements can be performed on a plurality of battery cells in the battery pack utilizing the balancing resistor, and the phenomenon of unbalanced charging (or discharging) in the storage battery pack can be reduced.

For example, when the monitoring unit 6312 acquires voltage information or current information of the non-intelligent device 641 (e.g., a storage battery) through the monitoring module 6314 to determine the remaining capacity of the storage battery, if it is determined that the remaining capacity of the battery cell is different from the preset capacity threshold, the balancing resistor and the battery cell specified by the controller may be connected in parallel (or in series) through the intelligent access control unit 6315, so as to obtain a balancing battery cell; and the storage battery is balanced based on the balancing battery cell so that the state of health of the storage battery meets a preset health threshold.

For example, when an online balancing operation is performed on a valve-regulated sealed lead-acid storage battery, the corresponding telemetry data includes: total voltage of the storage battery pack, charging/discharging current of the storage battery pack, capacity of each storage battery pack, voltage of a single battery of the storage battery pack, temperature of the single battery, internal resistance of the single battery, remaining capacity of the single battery, and the like.

The corresponding alarm information includes: at least one of high (or low) battery pack total voltage alarm, high (or low) single battery voltage alarm, over-high single battery internal resistance alarm, battery temperature upper limit (lower limit) exceeding alarm, high charging current alarm, battery pack charging state abnormity alarm, battery pack discharging state abnormity alarm, remaining discharging time alarm, battery pack state of health overlimit alarm, single battery state of health overlimit alarm, or storage battery pack state of unbalance overlimit alarm. The state of health is a ratio of an actual capacity to a preset capacity of the battery (or the battery pack).

For another example, when an online balancing operation is performed on a lithium series battery pack, the corresponding telemetry data includes: at least one of battery pack capacity, battery pack (or single battery) voltage, ambient temperature, battery pack temperature, PCBA temperature, battery temperature, battery pack charging current, battery pack discharging current, battery pack internal resistance, and battery pack state of health information.

The corresponding alarm information includes: at least one of battery pack charging state abnormality alarm information, battery pack discharging state abnormality alarm information, battery pack overcharge alar m information, battery pack overcurrent alarm information, battery pack discharge undervoltage alarm information, battery pack discharge overcurrent alarm information, battery charge overvoltage alarm information, battery discharge undervoltage alarm information, battery pack polarity reversal alarm information, ambient temperature alarm information, battery pack temperature alarm information, PCBA temperature alarm information, battery temperature alarm information, low ambient temperature alarm information, battery pack low capacity alarm information, battery pack temperature sensor failure alarm information, battery pack voltage sensor failure alarm information, battery pack current sensor failure alarm information, battery failure alarm information, or battery pack failure alarm information.

In a case where it is determined that the alarm information is received, the battery pack may be controlled in one of the following control manners: performing charging (or discharging) operation on the battery pack, turning off an alarm sound, charging the battery pack in an intelligent intermittent charging mode, charging the battery pack in a current-limited charging mode, changing the charging parameters of the battery pack, and changing the discharging parameters of the battery pack.

Through the monitoring and management operation described above, the storage battery can be monitored, false alarm information of the storage battery is reduced, deterioration analysis of the storage battery is more accurate, and maintenance efficiency of the storage battery is improved.

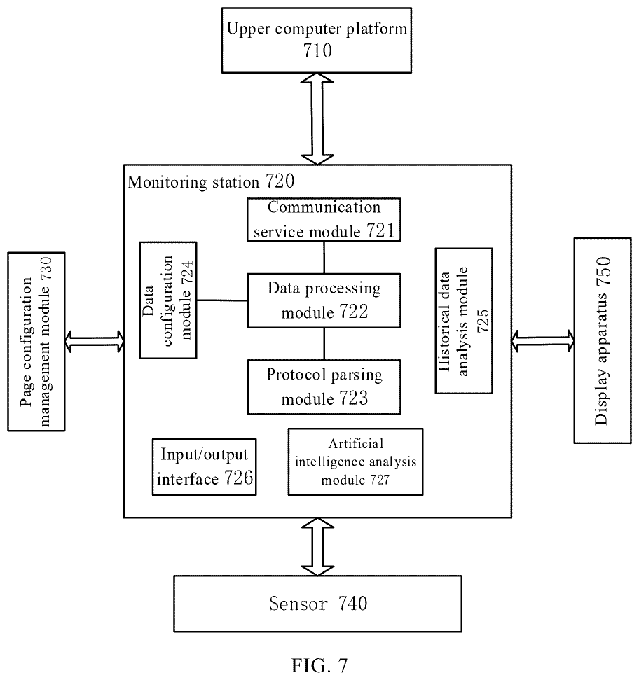

FIG. 7 shows a schematic diagram of operation control of the device monitoring system of an embodiment of the present disclosure. As shown in FIG. 7, the monitoring station 720 is connected to an upper computer platform 710 (e.g., a smart phone, a tablet PC, or a Personal Computer (PC)), a page configuration management module 730, a sensor 740, and a display apparatus 750.

The monitoring station 720 includes: a communication service module 721, a data processing module 722, a protocol parsing module 723, a data configuration module 724, a historical data analysis module 725, an input/output interface 726, and an artificial intelligence (AI) analysis module 727.

The page configuration management module 730 is configured to perform parameter configuration management, query control, version information upgrade and maintenance, and the like on each module in the monitoring station 720.

The sensor 740 is configured to sense smoke, water immersion information, on-off information of an air conditioner, lighting information, temperature and humidity information, thunder and lightning information and the like in the equipment room so as to acquire real-time environment information of the equipment room. For example, the sensor 740 may be a light control sensor, a buzzer sensor, a temperature and humidity sensor, a door magnetic sensor, an infrared sensor, a smoke sensor, and the like.

The display apparatus 750 is configured to display alarm information fed back by the monitoring station 720, set network connection information between the devices (for example, setting an Internet Protocol (IP) address, etc.), and provide an interactive interface for a user, so as to receive parameters set by the user.

A query instruction sent by a user is acquired through the page configuration management module 730, so as to acquire the telemetry data of the controlled device (such as an intelligent device or a non-intelligent device); or, the telemetry data of the controlled device is remotely acquired in a network interconnection mode based on a preset acquisition period.

The preset acquisition period may be obtained by reading the configuration file through the data configuration module 724. The telemetry data is obtained by the sensor 740 by monitoring the controlled device or the environment where the controlled device is located.

The monitoring station 720 determines whether to generate alarm information based on the acquired telemetry data, and in a case where it is determined that the alarm information is generated, displays the alarm information to the display apparatus 750, and further adjusts the controlled device in an adjustment mode matched with a type of the controlled device according to the alarm information.

For example, when a control instruction sent by the upper computer platform 710 is received, the monitoring station 720 parses the received control instruction through the protocol parsing module 723, and communicates with the controlled device through the input/output interface 726, so that the controlled device can be remotely operated, thereby changing the working state of the controlled device.

In this embodiment, false alarm information generated in the process of monitoring the battery is reduced by performing combined alarming on an intelligent device (or a non-intelligent device such as a storage battery). By adopting a linkage technology, when an alarm is generated, a storage battery balancing apparatus can be linked to remotely perform corresponding operations (such as charging or discharging operations) on the storage battery pack so as to improve the control capability towards the storage battery and reduce the fault rate of the storage battery. By adopting an improved storage battery internal resistance detection algorithm to identify the alarms regarding the temperature, current and the like generated by the battery monitoring module, the device monitoring system can achieve fine management of the storage battery, reduce false alarm information, prolong the service life of the storage battery, and improve the operation efficiency of the respective devices in the device monitoring system.

It should be understood that above embodiments are just examples for illustrating the principle of the present disclosure, however, the present disclosure is not limited thereto. Various modifications and variations can be made by a person skilled in the art without departing from the spirit and the scope of the present invention. These modifications and variations should be considered to be within the protection scope of the present disclosure.

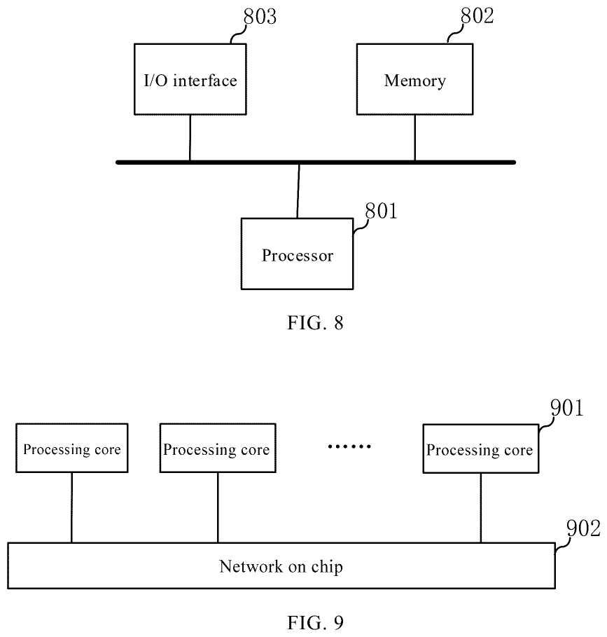

In a fourth aspect, an embodiment of the present disclosure provides an electronic device. FIG. 8 is a block diagram illustrating the configuration of an electronic device provided by an embodiment of the present disclosure.

Referring to FIG. 8, the embodiment of the present disclosure provides an electronic device, including: at least one processor 801, at least one memory 802, and one or more I/O interfaces 803 coupled between the processor 801 and the memory 802, where the memory 802 has stored therein one or more computer programs executable by the at least one processor 801, the one or more computer programs are executed by the at least one processor 801, so that the at least one processor 801 can execute the device monitoring methods described above.

In some embodiments, the at least one processor 801 performs remote data acquisition on the controlled device in a network interconnection mode to obtain telemetry data, which is data representing a real-time working state of the controlled device, determines whether to generate alarm information according to the telemetry data, the alarm information being used for representing that the controlled device is in an abnormal working state, and in a case where it is determined that the alarm information is generated, adjusts the controlled device in an adjustment mode matched with a type of the controlled device according to the alarm information.

It is noted that the at least one processor 801 is capable of implementing any one of the device monitoring methods of the embodiments of the present disclosure.

FIG. 9 is a block diagram illustrating the configuration of an electronic device provided by an embodiment of the present disclosure.

Referring to FIG. 9, the embodiment of the present disclosure provides an electronic device, which includes a plurality of processing cores 901 and a network on chip 902, where the plurality of processing cores 901 are all connected to the network on chip 902, and the network on chip 902 is configured for interaction between data of the plurality of processing cores 901 and external data.

One or more instructions are stored in the one or more processing cores 901, and the one or more instructions are executed by the one or more processing cores 901, so that the one or more processing cores 901 can execute the above-mentioned device monitoring methods.

In some embodiments, the one or more processing cores 901 can perform remote data acquisition on the controlled device in a network interconnection mode to obtain telemetry data, which is data representing a real-time working state of the controlled device, determine whether to generate alarm information according to the telemetry data, the alarm information being used for representing that the controlled device is in an abnormal working state, and in a case where it is determined that the alarm information is generated, adjust the controlled device in an adjustment mode matched with a type of the controlled device according to the alarm information.

It is to be noted that the at least one processing core 901 can implement any one of the device monitoring methods of the embodiments of the present disclosure.

In a fifth aspect, an embodiment of the present disclosure provides a computer-readable storage medium.

The computer-readable storage medium has stored thereon a computer program, which, when executed by a processor/processing core, implements the device monitoring methods described above. The computer-readable storage medium may be a volatile or non-volatile computer-readable storage medium.

An embodiment of the present disclosure further provides a computer program product including a computer-readable code or a nonvolatile computer-readable storage medium having computer-readable codes stored thereon, where the computer-readable code, when executed on a processor of an electronic device, causes the processor in the electronic device to implement the device monitoring methods as described above.

Those of ordinary skill in the art will appreciate that all or some steps of the above described method, functional modules/units in the system and apparatus may be implemented as software, firmware, hardware, and suitable combinations thereof. In a hardware implementation, the division between the functional modules/units mentioned in the above description does not necessarily correspond to the division of physical components; for example, one physical component may have multiple functions, or one function or step may be performed cooperatively by several physical components. Some or all physical components may be implemented as software executed by a processor, such as a CPU, a digital signal processor or microprocessor, or implemented as hardware, or implemented as an integrated circuit, such as an application specific integrated circuit. Such software may be distributed on a computer-readable storage medium which may include a computer storage medium (or non-transitory medium) or a communication medium (or transitory medium).

As is well known to those of ordinary skill in the art, the term computer storage medium includes volatile and nonvolatile, removable and non-removable medium implemented in any method or technology for storing information, such as computer-readable program instructions, data structures, program modules or other data. The computer storage medium includes, but is not limited to, a random access memory (RAM), read-only memory (ROM), an erasable programmable read-only memory (EPROM), a static random access memory (SRAM), a flash memory or any other memory technology, a portable compact disk read-only memory (CD-ROM), a digital versatile disk (DVD) or any other optical disk storage device, a magnetic cassette, a magnetic tape, a magnetic disk storage means or any other magnetic storage device, or any other medium which can be used to store the desired information and accessed by a computer. Moreover, it is well known to those ordinary skilled in the art that a communication medium typically includes computer-readable program instructions, a data structure, a program module, or other data in a modulated data signal, such as a carrier wave or other transport mechanism, and may include any information delivery medium.

The computer-readable program instructions described herein can be downloaded to respective computing/processing devices from a computer-readable storage medium or to an external computer or external storage device via a network, for example, the Internet, a local area network, a wide area network and/or a wireless network. The network may include copper transmission cables, optical transmission fibers, wireless transmission, routers, firewalls, switches, gateway computers and/or edge servers. A network adapter card or network interface in each computing/processing device receives computer-readable program instructions from the network and forwards the computer-readable program instructions for storage in a computer-readable storage medium within the respective computing/processing device.

Computer program instructions for carrying out operations of the present disclosure may be assembler instructions, instruction set architecture (ISA) instructions, machine instructions, machine-related instructions, microcodes, firmware instructions, state setting data, or source or object codes written in any combination of one or more programming languages, including an object oriented programming language such as Smalltalk, C++, or the like, and conventional procedural programming languages, such as the “C” programming language or similar programming languages. The computer-readable program instructions may execute entirely on the user computer, partly on the user computer, as a stand-alone software package, partly on the user computer and partly on a remote computer or entirely on the remote computer or server. In the latter scenario, the remote computer may be connected to the user computer through any type of network, including a local area network (LAN) or a wide area network (WAN), or by connecting to an external computer (for example, through the Internet provided by an Internet service provider). In some embodiments, aspects of the present disclosure are implemented by personalizing an electronic circuit, such as a programmable logic circuit, a field programmable gate array (FPGA), or a programmable logic array (PLA), with state information of computer-readable program instructions, which can execute the computer-readable program instructions.

The computer program product described herein may be specifically implemented in hardware, software, or a combination thereof. In an optional embodiment, the computer program product is specifically embodied in a computer storage medium, while in another optional embodiment, the computer program product is specifically embodied in a software product, such as a software development kit (SDK) or the like.

Various aspects of the present disclosure have been described herein with reference to flowchart illustrations and/or block diagrams of methods, apparatus (systems), and computer program products according to embodiments of the present disclosure. It will be understood that each block of the flowchart illustrations and/or block diagrams, and combinations of blocks in the flowchart illustrations and/or block diagrams, can be implemented by computer-readable program instructions.

These computer-readable program instructions may be provided to a processor of a general purpose computer, special purpose computer, or other programmable data processing apparatus to produce a machine, such that the instructions, when executed via the processor of the computer or other programmable data processing apparatus, create means for implementing the functions/acts specified in flowchart and/or block diagram block or blocks. These computer-readable program instructions may also be stored in a computer-readable storage medium, and direct a computer, a programmable data processing apparatus, and/or other devices to function in a particular manner, such that the computer-readable medium having the instructions stored therein includes an article of manufacture including instructions for implementing aspects of the function/act specified in the flowchart and/or block diagram block or blocks.

The computer-readable program instructions may also be loaded onto a computer, other programmable data processing apparatus, or other device to cause a series of operational steps to be performed on the computer, other programmable data processing apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present disclosure. In this regard, each block in the flowchart or block diagram may represent a functional block, a program segment, or a portion of instructions including one or more executable instructions for implementing the specified logical function(s). In some alternative implementations, the functions shown in the blocks may occur out of the order shown in the figures. For example, two blocks shown in succession may, in fact, be executed substantially concurrently, or may sometimes be executed in the reverse order, depending upon the functionality involved. It will also be noted that each block in the block diagram and/or flowchart, and combinations of blocks in the block diagram and/or flowchart, may be implemented by a special purpose hardware-based system which performs the specified functions or acts, or by combinations of special purpose hardware and computer instructions.

The present disclosure has disclosed exemplary embodiments, and although specific terms are employed, they are used and should be interpreted merely in a generic and descriptive sense, not for purposes of limitation. In some instances, as would be apparent to one skilled in the art, features, characteristics and/or elements described in connection with a particular embodiment may be used alone or in combination with features, characteristics and/or elements described in connection with another embodiment, unless expressly stated otherwise. It will, therefore, be understood by those skilled in the art that various changes in form and details may be made therein without departing from the scope of the present disclosure as set forth in the appended claims.

1. A device monitoring method, comprising:
remotely acquiring data of a controlled device in a network interconnection mode to obtain telemetry data, which is data representing a real-time working state of the controlled device;
determining whether to generate alarm information according to the telemetry data, wherein the alarm information is used for representing that the controlled device is in an abnormal working state; and
in a case where it is determined that the alarm information is generated, adjusting the controlled device in an adjustment mode matched with a type of the controlled device according to the alarm information.

2. The method of claim 1, wherein the controlled device comprises a first type device having computation processing capability and a second type device having no computation processing capability and passively receiving control information;
wherein before remotely acquiring data of the controlled device in the network interconnection mode to obtain the telemetry data, the method further comprises:
acquiring environment information of the first type device using an environment sensor, so as to determine whether the first type device works in a safe scenario;
acquiring environment information of the second type device using a video acquisition assembly, so as to determine whether the second type device works in a safe scenario; and
in a case where it is determined that the first type device and the second type device each work in the safe scenario, performing the step of remotely acquiring data of the controlled device in the network interconnection mode to obtain the telemetry data.

3. The method of claim 2, wherein the second type device comprises at least one of a lead-acid storage battery, a lead-acid storage battery pack, a lithium series battery, or a lithium series battery pack.

4. The method of claim 1, wherein the controlled device comprises a storage battery; remotely acquiring data of the controlled device in the network interconnection mode to obtain the telemetry data comprises:
remotely acquiring the telemetry data of the controlled device in the network interconnection mode based on a preset acquisition period;
wherein the telemetry data comprises at least one of a working parameter, temperature information, or capacity information of the storage battery.

5. The method of claim 4, wherein determining whether to generate alarm information according to the telemetry data comprises:
generating state of health overlimit alarm information in a case where it is determined that the telemetry data comprises a state of health of the controlled device and the state of health exceeds a preset health threshold, wherein the state of health is a ratio of an actual capacity of the storage battery to a preset capacity of the storage battery;
generating temperature alarm information in a case where it is determined that the telemetry data comprises a temperature value of the controlled device and the temperature value is not within a preset temperature range; and
generating working parameter alarm information in a case where it is determined that the telemetry data comprises the working parameter of the controlled device and the working parameter is not within a preset parameter range.

6. The method of claim 5, wherein adjusting the controlled device in the adjustment mode matched with the type of the controlled device according to the alarm information comprises:
in a case where it is determined that the controlled device is a storage battery and the alarm information is the state of health overlimit alarm information, balancing the storage battery so that the state of health of the storage battery meets the preset health threshold; and
in a case where it is determined that the controlled device is a storage battery and the alarm information is the working parameter alarm information, adjusting a charging parameter or a discharging parameter of the storage battery so that the working parameter of the storage battery meets the preset parameter range.

7. The method of claim 6, wherein balancing the storage battery so that the state of health of the storage battery meets the preset health threshold comprises:
acquiring remaining capacities of a plurality of battery cells in the storage battery;
in a case where it is determined that a remaining capacity of at least one battery cell is not within a preset capacity threshold range, controlling, via an access control unit, a connection relationship between a balancing resistor and the at least one battery cell to form a balancing battery cell; and
balancing the storage battery based on the balancing battery cell so that the state of health of the storage battery meets the preset health threshold.

8. The method of claim 5, wherein the working parameter of the controlled device comprises: at least one of voltage information, current information, or internal resistance information;
generating working parameter alarm information in a case where it is determined that the telemetry data comprises the working parameter of the controlled device and the working parameter is not within the preset parameter range comprises:
generating voltage alarm information in a case where it is determined that the telemetry data comprises the voltage information of the controlled device and that voltage of the controlled device is not within a preset voltage threshold range;
generating current alarm information in a case where it is determined that the telemetry data comprises current information of the controlled device and that current of the controlled device exceeds a preset current threshold; and
generating internal resistance overlimit alarm information in a case where it is determined that the telemetry data comprises the internal resistance information of the controlled device and an internal resistance value exceeds a preset internal resistance threshold.

9. The method of claim 1, wherein the controlled device comprises a storage battery, and the alarm information comprises: alarm information that a capacity of the storage battery is lower than a preset capacity;
adjusting the controlled device in the adjustment mode matched with the type of the controlled device according to the alarm information comprises:
charging the storage battery in an intermittent charging mode and/or a current-limited charging mode so as that the capacity of the storage battery meets the preset capacity.

10. The method of claim 1, wherein the controlled device comprises a storage battery, the alarm information further comprises: at least one of battery polarity reversal alarm information of the storage battery, battery pack polarity reversal alarm information of the storage battery, or sensor failure alarm information of the controlled device;
wherein a sensor of the controlled device is used for sensing a working parameter of the controlled device.

11. A device monitoring apparatus, comprising:
a data acquisition module configured to remotely acquire data of a controlled device in a network interconnection mode to obtain telemetry data, which is data representing a real-time working state of the controlled device;
a generation module configured to determine whether to generate alarm information according to the telemetry data, wherein the alarm information is used for representing that the controlled device is in an abnormal working state; and
an adjustment module configured to, in a case where it is determined that the alarm information is generated, adjust the controlled device in an adjustment mode matched with a type of the controlled device according to the alarm information.

12. A device monitoring system, comprising: a controlled device, a server and a device monitoring apparatus;
wherein the device monitoring apparatus is electrically connected to the server and the controlled device; the controlled device comprises at least one first type device having computation processing capability and at least one second type device having no computation processing capability and passively receiving control information;
the device monitoring apparatus is configured to perform the device monitoring method of claim 1; and
the server is configured to, based on a communication interface provided by a preset communication converter, acquire the telemetry data acquired by the device monitoring apparatus and operation data of the first type device, store the telemetry data and the operation data, interact with the first type device through the device monitoring apparatus, and provide preset service information for the first type device.
